(19) United States
(12) Patent Application Publication
(10) Pub. No.: US 2026/0125595 A1
(43) Pub. Date: May 7, 2026

(54) LUMINOPHORE, METHOD FOR PRODUCING A LUMINOPHORE AND RADIATION-EMITTING COMPONENT

(71) Applicant: ams-OSRAM International GmbH, Regensburg (DE)

(72) Inventors: Philipp PUST, Langquaid (DE); Barbara HUCKENBECK, Denklingen (DE)

(21) Appl. No.: 19/118,366

(22) PCT Filed: Oct. 4, 2023
(86) PCT No.: PCT/EP2023/077426

§ 371 Date: Apr. 4, 2025

(30) Foreign Application Priority Data
Oct. 12, 2022 (DE) 102022126567.6

(51) Int. Cl. C09K 11/77; H01S 5/00

(52) U.S. Cl. CPC C09K 11/7774; H01S 5/0078

(57) ABSTRACT

A luminophore is disclosed which includes a host material that includes an oxide, along with an activator element containing a rare earth element in two different valence states—the second being higher than the first. Also disclosed are a method for producing the luminophore and a radiation-emitting component incorporating the luminophore.

### RELATED APPLICATIONS

This application is a US National Stage application, filed under 35 U.S.C. § 371, of International Application PCT/EP2023/077426, filed on Oct. 4, 2023, and claims priority to German patent application 10 2022 126 567.6, filed on Oct. 12, 2022, the entirety of the above listed applications is incorporated herein by reference.

### FIELD

A luminophore, a method for producing a luminophore and a radiation-emitting component are disclosed.

### SUMMARY

At least one embodiment relates to a luminophore with improved properties. At least one further embodiment relates to a method for producing a luminophore with improved properties. At least one further embodiment relates to a radiation-emitting component with improved properties. The various embodiments can use

A luminophore is disclosed. According to at least one embodiment, the luminophore comprises a host material containing an oxide, an activator element comprising a rare earth element having a first valency, and the rare earth element having a second valency, wherein the second valency is greater than the first valency.

The luminophore described here therefore contains the same rare earth element with two different valencies, the first valency and the second valency.

The term “luminophore” is understood here and in the following to mean a wavelength conversion substance or conversion substance for short, i.e. a material that is set up to absorb and emit electromagnetic radiation. In particular, the luminophore absorbs electromagnetic radiation that has a different wavelength maximum than the electromagnetic radiation emitted by the luminophore. For example, the luminophore absorbs radiation with a wavelength maximum at shorter wavelengths than the emission maximum and thus emits radiation with an emission maximum shifted towards red. Pure scattering or pure absorption are not understood as wavelength-converting in the present case.

Here and in the following, “host material” means a crystalline material, for example a ceramic material, into which the rare earth element is incorporated. The luminophore is therefore a ceramic material, for example. In particular, the host material forms a host lattice, which is made up of a generally periodically repeating three-dimensional unit cell. In other words, the unit cell is the smallest recurring unit of the crystalline host lattice. The elements contained in the host material, the rare earth element with the first valency and the rare earth element with the second valency, each occupy fixed positions in the unit cell, so-called point positions.

The term “valency” in relation to a specific element refers to how many elements with a single opposite charge are required in a chemical compound in order to achieve a charge balance. The term “valency” therefore includes the charge number of the element. Here and in the following, first valency and second valency are to be understood as two different valencies. For example, the first valency is valency 3 and the second valency is valency 4. The rare earth element can thus be present in the luminophore in trivalent and tetravalent form. In particular, the trivalent rare earth element has a triple positive charge and the tetravalent rare earth element has a quadruple positive charge.

The rare earth element with the first valency has the function of an activator element in the luminophore. The activator element changes the electronic structure of the host material in such a way that electromagnetic radiation of a first wavelength range can be absorbed by the luminophore. This so-called primary radiation can excite an electronic transition in the luminophore, which can return to the ground state by emitting electromagnetic radiation of a second wavelength range, also known as secondary radiation. The activator element, which is introduced into the host material, is thus responsible for the wavelength-converting properties of the luminophore. In particular, the secondary radiation has wavelengths in the visible spectral range.

Part of the rare earth element is present in oxidized form, i.e. with a higher, second valency. In particular, the rare earth element with the second valency does not have the function of an activator element or does not lead to a conversion of the primary radiation into a secondary radiation, which is in the visible spectral range of electromagnetic radiation. In order to differentiate between the rare earth element with first valency and with second valency, only the rare earth element with first valency is referred to here and in the following as the activator element.

Rare earth elements include the chemical elements of the 3rd subgroup of the periodic table as well as the lanthanides. Rare earth elements are generally selected from the group formed by scandium, yttrium, lanthanum, cerium, praseodymium, neodymium, promethium, samarium, europium, gadolinium, terbium, dysprosium, holmium, erbium, thulium, ytterbium and lutetium.

The inventors have recognized that the presence of the rare earth element with the second valency, which, in particular in contrast to the rare earth element with the first valency, is not an activator element or leads to secondary radiation that lies outside the visible spectral range, can reduce the quantum efficiency of the luminophore and thus the brightness of the electromagnetic radiation emitted by a component containing the luminophore. By suitably varying the ratio of rare earth element with first valency and rare earth element with second valency, the brightness required for an application of a radiation-emitting component, for example an LED (LED: light-emitting diode), in which the luminophore is used, can thus be continuously adjusted.

In so-called modular system platforms for LEDs, individual components are interchangeable. The aim is to provide a modular system in which as many different LED derivatives as possible can be used, covering different colors, white color locations and, in particular, brightnesses. Up to now, different brightnesses have mainly been implemented using different chip sizes and chip types in order to cover a wide range of brightnesses. The specific designs of the chips and possibly low individual volumes of individual derivatives mean that a complex chip portfolio must be kept available in order to be able to provide the modular system platforms over a long period of time, for example for longer than 10 years, which is particularly relevant in the automotive sector. This results in additional chip costs by a factor of two to three compared to standard chips.

Until now, it has not been possible to generate different brightnesses of an LED with one type of chip without either changing the operating current or changing the chip in terms of its fit, shape or function. Such a change is made, for example, via narrower light emission paths or via black material, such as carbon black particles, in the light emission path. However, carbon black particles in particular also change the external visual impression, which is generally undesirable.

A previously known method of grading the brightness of an LED is, for example, by adjusting it using different chip sizes. Additional dimming using special bond pad designs, for example, is also known. This approach results in high production costs, as the LED designs required for different brightnesses are only needed in small quantities and the individual LED chips are therefore very expensive in their manufacture.

Furthermore, it is possible in principle to introduce an additional non-conversion substance into the LED that absorbs radiation but has no quantum efficiency in order to keep the influence on the color of the emitted radiation as low as possible. However, this creates the problem that the actual conversion substance and the additional non-conversion substance, which has no quantum efficiency, do not have exactly the same excitation optimum due to their different compositions. An LED with an additional non-conversion substance therefore has a different overall absorption, which in turn entails a complex adjustment of the color location of the emitted radiation by adjusting the conversion substance mixture. Thus, it has not yet been possible to produce and ensure a reproducible reduced quantum efficiency of a converter, as this has only been achieved by introducing foreign elements, which cause unwanted absorption and this leads to a change in the emission color.

With the luminophore described here, on the other hand, the brightness of the emitted radiation of a radiation-emitting component, for example an LED, can be reproducibly adjusted, as the position of the absorption maximum is maintained with unchanged high absorption, i.e. a high efficiency, and at the same time a reduced quantum yield can be ensured. As a result, the emission color of the radiation-emitting component is not affected and the required brightness can be adjusted continuously. Since the composition of the luminophore does not change in principle and only part of the rare earth element has a changed valency, only the brightness of the emitted radiation can be adjusted while maintaining the properties of the luminophore. A complex adjustment of a luminophore mixture for setting the exact color location with changed brightness is therefore not necessary. The external optical impression of a component containing the luminophore also remains unchanged, which would not be the case if, for example, carbon black particles or pigments were used.

This has many advantages in terms of application. For example, the luminophore described here can be used alone or in a mixture with a basic luminophore, which differs from the luminophore only in that it is free of the rare earth element with second valency. This allows the brightness of the component containing the seamlessly, for example an LED, to be adjusted flexibly and without gaps, while maintaining the color location, for example the white color location. This also reduces or avoids the effort required for color location control, as all the properties of the luminophore, in particular the position of the absorption maximum, are retained in comparison to the base luminophore, apart from the brightness.

The seamless adjustment of brightness also means that different sizes and types of components, such as LED chips, are not required, which reduces the complexity of a portfolio of components, especially in the case of required long availabilities such as for automotive products. Such a harmonization of a portfolio can also lead to further cost savings, as a higher volume of only one or fewer component types needs to be provided.

According to at least one embodiment, the host material is a garnet. With garnets as host materials, luminophores with a high quantum yield of, for example, over 95% can be provided if suitably doped with an activator element. Here and in the following, a garnet is understood to be an oxide which can be represented, for example, by the general formula (Y, Lu, Gd, Tb)₃(Al₁₋ₓ,Gaₓ)₅O₁₂ with 0≤x≤1. The elements listed in the first bracket may be present in the garnet individually or in combination with each other, depending on the type of garnet. Specific examples of garnets include yttrium aluminum garnet (YAG) with the general formula Y₃Al₅O₁₂ and lutetium aluminum garnet (LuAG) with the general formula Lu₃Al₅O₁₂.

Here and in the following, luminophores and the host material are described using molecular formulas. The elements listed in the molecular formulae are present in charged form. Here and in the following, elements and/or atoms in relation to the molecular formulae of the luminophores or host materials therefore refer to ions in the form of cations and anions, even if this is not explicitly stated. This also applies to element symbols if these are given without a charge number for the sake of clarity.

It is possible with the given molecular formulae that the luminophore or the host material has further elements, for example in the form of contaminations. Taken together, these contaminations have a maximum of 5 mol %, in particular a maximum of 1 mol %, for example, a maximum of 0.1 mol %.

According to at least one further embodiment, the rare earth element is cerium (Ce). Ce may thus be present in the luminophore as an activator element if it is present with the first valency. If it is present with the second valency, it can be present as a non-activator element, or at least lead to secondary radiation that lies outside the visible spectral range. Ce as an activator element, especially in combination with a garnet as a host lattice, leads to a stable luminophore with high quantum efficiency.

According to at least one further embodiment, the first valency is three and the second valency is four. Ce is thus present in the luminophore as Ce³⁺ and as Ce⁴⁺. Ce³⁺ with the lower first valency is thus present as an activator element. Garnet luminophores with Ce³⁺ as the activator element can have a quantum yield of over 95% and a remission of less than 10% in the blue spectral range of electromagnetic radiation, depending on the composition of the garnet at around 460 nm. The activator element Ce³⁺ is activated by photons, especially blue photons, and shows a 4f1-5d0<->4f0-5d1 transition, the relaxation of which typically releases light in the visible spectral range. If, for example, YAG is used as the garnet, the doped system YAG:Ce³⁺ releases an emission in the yellow spectral range with a peak maximum of the wavelength in the range 540 nm to 580 nm and a half-width in the range 110 nm to 130 nm.

The additional introduction of Ce⁴⁺ or the partial conversion of Ce³⁺ into Ce⁴⁺ does not change the emission in the visible spectral range compared to the base luminophore, which contains only Ce³⁺, but the high absorption and the position of the absorption maximum in the blue spectral range are retained. Thus, the color location of the radiation-emitting component containing the luminophore described here is not changed compared to a luminophore containing Ce only as Ce³⁺. For example, a white color location of an LED is not affected by the presence of Ce⁴⁺ in the luminophore. With an increasing proportion of Ce⁴⁺ in the luminophore, the absorption in the UV range, i.e. in the range from 300 nm to 400 nm, is also increased. Increased absorption in the UV range can lead to the absorption of short-wave components of the primary radiation, which do not contribute to brightness but can accelerate the ageing of package materials such as silicone or epoxy. By partially replacing Ce³⁺ with Ce⁴⁺, for example by oxidizing Ce³⁺ to Ce⁴⁺, the quantum yield or efficiency of the luminophore can thus be adjusted as desired between 0% and 100%, in particular between 20% and 100%, for example between 50% and 100% of the quantum yield of a reference luminophore without Ce⁴⁺ content (base luminophore), while maintaining the high absorption and exact position of the absorption maximum. In addition, the lifetime of a component containing the luminophore can be increased.

According to at least one further embodiment, the luminophore has the general formula (Y, Lu, Gd, Tb)₃(Al₁₋ₓ,Gaₓ)₅O₁₂:Ce_{y}³⁺Ce_{1-y}⁴⁺ where 0≤x≤1 and 0<y<1. The host material is thus a garnet of the formula (Y, Lu, Gd, Tb)₃(Al₁₋ₓ,Gaₓ)₅O₁₂, the activator element, i.e. the rare earth element with first valency is Ce³⁺ and the rare earth element with second valency is Ce⁴⁺.

According to at least one embodiment, the luminophore is free of divalent co-dopants, in particular free of Mg²⁺. Co-dopants are understood here and in the following to be elements that are additionally introduced into the host material in addition to the activator element or the rare earth element with the second valency.

According to at least one further embodiment, the luminophore has an absorption range with an absorption maximum, wherein the absorption maximum has a position which is substantially identical to a position of an absorption maximum of a base luminophore, wherein the base luminophore differs from the luminophore only in that it is free of the rare earth element having the second valency.

“Substantially identical” here and in the following means that two quantities to be compared are exactly identical, differ only within the scope of measurement inaccuracies or differ only to such an extent that they are not perceptible to an external observer. This also includes deviations of up to 5%, in particular up to 2%, for example up to 1%.

The basic luminophore is understood here and in the following to be a composition which differs from the luminophore described here only in that it does not contain a rare earth element with the second valency.

The basic luminophore therefore does not have a reduced quantum yield like the luminophore described here, as the activator element in the basic luminophore is not partially replaced by the second-valency rare earth element. The higher the proportion of rare earth element with second valency, the lower the proportion of activator element, the lower the quantum yield of the luminophore. For example, if the luminophore has the formula (Y, Lu, Gd, Tb)₃(Al₁₋ₓ,Gaₓ)₅O₁₂:Ce_{y}³⁺Ce_{1-y}⁴⁺, then the basic luminophore is (Y, Lu, Gd, Tb)₃(Al₁₋ₓ,Gaₓ)₅O₁₂:Ce³⁺. However, due to the otherwise identical composition of the luminophore and the base luminophore, the position of the absorption maximum remains unchanged, which means that the color location of the luminophore, which is determined using fluorescence spectroscopy, for example, remains unaffected.

According to at least one embodiment, the absorption range of the luminophore is at least in the UV to blue wavelength range of the electromagnetic spectrum. The absorption range of the luminophore is thus in the range 300 nm to 500 nm. The position of the absorption maximum can be in the range 440 nm to 470 nm, for example.

According to at least one further embodiment, the luminophore has a quantum efficiency that is reduced compared to a quantum efficiency of a base luminophore, wherein the base luminophore differs from the luminophore only in that it is free of the rare earth element with the second valency. The base luminophore therefore does not have a reduced quantum yield like the luminophore described here. The higher the proportion of rare earth element with second valency is in the luminophore, the lower the proportion of activator element, the lower the quantum yield of the luminophore. For example, if the luminophore has the formula (Y, Lu, Gd, Tb)₃(Al₁₋ₓ,Gaₓ)₅O₁₂:Ce_{y}³⁺Ce_{1-y}⁴⁺, then the basic luminophore is (Y, Lu, Gd, Tb)₃(Al₁₋ₓ,Gaₓ)₅O₁₂:Ce³⁺.

According to at least one further embodiment, an electromagnetic radiation emitted by the luminophore has a dominant wavelength which is substantially identical to a dominant wavelength of a base luminophore, wherein the base luminophore differs from the luminophore only in that it is free of the rare earth element having the second valency. For example, if the luminophore has the formula (Y, Lu, Gd, Tb)₃(Al₁₋ₓ,Gaₓ)₅O₁₂:Ce_{y}³⁺Ce_{1-y}⁴⁺, then the base luminophore is (Y, Lu, Gd, Tb)₃(Al₁₋ₓ,Gaₓ)₅O₁₂:Ce³⁺.

To determine the dominant wavelength of the electromagnetic radiation emitted by the luminophore, a straight line is drawn in the CIE standard diagram from the white point through the color location of the electromagnetic radiation. The intersection of the straight line with the spectral color line delimiting the CIE standard diagram denotes the dominant wavelength of the electromagnetic radiation. In general, the dominant wavelength differs from the wavelength of the emission maximum.

An unchanged dominant wavelength of the luminophore compared to a base luminophore means that the color location of the luminophore, which can be determined for example by fluorescence spectroscopy, is unaffected by the partial replacement of the rare earth element with the first valency, for example Ce³⁺, by the rare earth element with the second valency, for example Ce⁴⁺.

According to at least one further embodiment, an electromagnetic radiation emitted by the luminophore has a half-width which is substantially identical to a half-width of a base luminophore, wherein the base luminophore differs from the luminophore only in that it is free of the rare earth element having the second valency. For example, if the luminophore has the formula (Y, Lu, Gd, Tb)₃(Al₁₋ₓ, Gaₓ)₅O₁₂:Ce_{y}³⁺Ce_{1-y}⁴⁺, then the base luminophore is (Y, Lu, Gd, Tb)₃(Al₁₋ₓ, Gaₓ)₅O₁₂:Ce³⁺. The almost unchanged half width is due to the almost unchanged emission behavior of the luminophore compared to the base luminophore.

According to at least one further embodiment, further specification parameters of the luminophore are also substantially unchanged compared to a base luminophore as described above. Further specification parameters include, for example, particle size, morphology, scattering properties and body color of the luminophore powder.

According to at least one further embodiment, the luminophore has a brightness which decreases with increasing proportion of the rare earth element having the second valency in the luminophore. Using the example of the luminophore (Y, Lu, Gd, Tb)₃(Al₁₋ₓ,Gaₓ)₅O₁₂:Ce_{y}³⁺Ce_{1-y}⁴⁺ where 0≤x≤1 and 0<y<1, the brightness is therefore greater with a large y than with a small y. The brightness of the luminophore described here is therefore continuously adjustable.

A method for producing a luminophore is further disclosed. The method is suitable for producing a luminophore as described herein. All features disclosed in connection with the luminophore thus also apply to the method and vice versa.

According to at least one embodiment, the method comprises the steps of
providing a base luminophore comprising
a host material containing an oxide, and
an activator element comprising a rare earth element with a first valency,
oxidation of the base luminophore to a luminophore comprising
the host material containing an oxide,
the activator element comprising a rare earth element having a first valency, and
the rare earth element having a second valency, the second valency being greater than the first valency.

The method can thus be used to refine a basic luminophore into a luminophore that has a reduced and continuously adjustable quantum efficiency by oxidizing part of the activator element to the rare earth element having the second valency. The more rare earth element with first valency is oxidized to the rare earth element with second valency, the more reduced are the quantum efficiency and thus also the brightness of the emitted radiation.

The production of the luminophore is not significantly more expensive than that of the basic luminophore and, in particular, does not require expensive raw materials such as gallium or scandium oxide, which means that the production costs of the luminophore and a component containing the luminophore are not significantly increased. The luminophore described here can thus be produced and provided cost-effectively with reproducible lower quantum efficiency.

The cost-effective production of the luminophore is a simple post-treatment of a base luminophore. The method can also save further costs, as no additional luminophores, which do not have quantum efficiency, or other foreign elements are provided to reduce the brightness of a luminophore, but a single base luminophore can be used to generate different brightnesses of the resulting, refined luminophore depending on the application. This means that no extra costs are generated for the provision of different luminophores and thus for the creation of new formulations to adjust the color location of the emitted radiation.

According to at least one embodiment, the oxidation takes place by heating. According to at least one embodiment, the oxidation takes place at a temperature from the range including 350° C. to including 1400° C., in particular from the range including 600° C. to including 1200° C., for example from the range including 600° C. to including 1000° C. Thus, the method can be carried out at moderate to high temperatures and oxidation takes place by post-sintering of the base luminophore to form the luminophore. The higher the temperature selected, the higher the proportion of oxidized Ce⁴⁺ in the resulting luminophore and thus the lower its quantum efficiency. The resulting brightness of the emitted radiation can thus be controlled via the temperature in the method.

According to at least one further embodiment, the oxidation is carried out in air or oxygen. The oxidation or post-sintering of the base luminophore thus takes place under oxidizing conditions.

According to at least one embodiment, the oxidation is carried out for a period of from including one hour up to and including five hours, for example three hours.

According to at least one further embodiment, the base luminophore (Y, Lu, Gd, Tb)₃(Al₁₋ₓ,Gaₓ)₅O₁₂:Ce³⁺ where 0≤x≤1 is provided and oxidized to the luminophore (Y, Lu, Gd, Tb)₃(Al₁₋ₓ,Gaₓ)₅O₁₂:Ce_{y}³⁺Ce_{1-y}⁴⁺ where 0≤x≤1 and 0<y<1.

According to at least one embodiment, no divalent co-dopants, in particular no Mg²⁺, are used in the method.

A radiation-emitting component is further disclosed. The radiation-emitting component is arranged and intended to contain a luminophore described herein. All features disclosed in connection with the luminophore thus also apply to the radiation-emitting component and vice versa.

According to at least one embodiment, the radiation-emitting component comprises
a semiconductor chip that emits electromagnetic radiation of a first wavelength range during operation,
a conversion element comprising a luminophore described herein which converts electromagnetic radiation of the first wavelength range into electromagnetic radiation of a second wavelength range which is partially different from the first wavelength range.

The electromagnetic radiation of the first wavelength range forms the emission spectrum of the semiconductor chip and is also referred to as primary radiation.

The semiconductor chip is, for example, a light-emitting diode chip or a laser diode chip. The component can therefore be a light-emitting diode (LED) or a laser. In at least one example, the semiconductor chip has an epitaxially grown semiconductor layer sequence with an active zone that is suitable for generating electromagnetic radiation. For example, the active zone has for this a pn junction, a double heterostructure, a single quantum well or a multiple quantum well structure.

During operation, the semiconductor chip can emit electromagnetic radiation, for example from the ultraviolet spectral range and/or from the visible spectral range, in particular from the blue spectral range. The primary radiation thus has wavelengths from the range 300 nm to 500 nm, in particular 400 nm to 460 nm, for example.

The conversion element is arranged in particular on the radiation exit surface of the semiconductor chip and is located, for example, in the beam path of the semiconductor chip, so that at least some of the radiation emitted by the semiconductor chip strikes the conversion element.

The luminophore in the conversion element converts electromagnetic radiation of the first wavelength range into electromagnetic radiation of a second wavelength range. The electromagnetic radiation of the second wavelength range forms the emission spectrum of the luminophore and is also referred to as secondary radiation.

The electromagnetic radiation of the second wavelength range is at least partially different from the first wavelength range. The luminophore contained in the conversion element or of which the conversion element is made imparts wavelength-converting properties to the conversion element. For example, the conversion element only partially converts the electromagnetic radiation of the semiconductor chip into electromagnetic radiation of the second wavelength range, while a further part of the electromagnetic radiation of the semiconductor chip is transmitted by the conversion element. In this case, the radiation-emitting component emits mixed light, which is composed of electromagnetic radiation of the first wavelength range and electromagnetic radiation of the second wavelength range. The mixed light includes, for example, white light. If the primary radiation is completely converted by the conversion element and/or if there is no transmission of primary radiation by the conversion element, this is referred to as full conversion. In this case, the radiation-emitting component emits the secondary radiation emitted by the conversion element.

Due to the nature of the luminophore described here, the desired final brightness of the radiation-emitting component can be continuously adjusted while the brightness of the primary radiation emitted by the semiconductor chip remains constant, since the quantum efficiency of the luminophore can be adjusted depending on the proportion of rare earth element with second valency. The color location of the total emitted radiation is retained without the need to develop a new formulation of a luminophore mixture for adjusting the color location.

A wide range of brightnesses can therefore be provided with just one type and size of semiconductor chip and thus of radiation-emitting component. In particular, special chip types that are required for certain applications, for example in the automotive sector, can thus be procured or produced on a large scale and the desired brightnesses can be set using the appropriate luminophore, which has a reproducibly reduced quantum efficiency. Additional costs that were previously incurred due to the need to provide different chip types can thus be reduced. A chip portfolio can thus be harmonized by using the luminophore described here without changing the properties of the radiation-emitting component with regard to its specification, in particular the emission color and the external optical impression. An external optical impression of the component, which is not changed by the introduction of the luminophore described here, cannot be realized with carbon black particles or other pigments.

According to at least one embodiment, the conversion element contains only the luminophore. The luminophore is thus used as the sole luminophore in the conversion element. With the luminophore described here, the desired brightness of the radiation-emitting component can be continuously adjusted depending on the proportion of the rare earth element with second valency.

According to at least one embodiment, the conversion element additionally comprises a base luminophore, wherein the base luminophore differs from the luminophore only in that it is free of the rare earth element with the second valency. The conversion element thus contains a mixture of unrefined base luminophore and refined luminophore with reduced quantum efficiency, whereby a flexible and seamless adjustment of the brightness of the radiation-emitting component can be obtained. While maintaining the absorption and position of the absorption maximum of the base luminophore, a quantum efficiency between 50% and 100% of the quantum efficiency of the base luminophore can be set, depending on the selected luminophore and the ratio between base luminophore and luminophore.

Regardless of whether the luminophore is used alone or together with the base luminophore in the conversion element, the color location of the base luminophore is retained. To ensure that the radiation-emitting component, which contains the luminophore and optionally the base luminophore, also has the same color location as a radiation-emitting component in which only the base luminophore is present, the amount of added luminophore and/or the mixing ratio between the luminophore and base luminophore can be adjusted accordingly.

According to at least one embodiment, the conversion element contains (Y, Lu, Gd, Tb)₃(Al₁₋ₓ,Gaₓ)₅O₁₂:Ce_{y}³⁺Ce_{1-y}⁴⁺ where 0≤x≤1 and 0<y<1 as the sole luminophore.

According to at least one further embodiment, the conversion element comprises a mixture of the luminophore (Y, Lu, Gd, Tb)₃(Al₁₋ₓ,Gaₓ)₅O₁₂:Ce_{y}³⁺Ce_{1-y}⁴⁺ wherein 0≤x≤1 and 0<y<1 and the base luminophore (Y, Lu, Gd, Tb)₃(Al₁ₓ, Gaₓ)₅O₁₂:Ce³⁺ wherein 0≤x≤1.

According to at least one embodiment, the ratio of luminophore to base luminophore in the conversion element is selected from 100:0, 80:20, and 60:40.

The luminophore and optionally the base luminophore can be embedded in a matrix material. The luminophore and optionally the base luminophore are then present in particle form. According to one embodiment, the matrix material is selected from a group comprising polymers and glass. The polymers that can be selected include, for example, polystyrene, polysiloxane, polysilazane, PMMA, polycarbonate, polyacrylate, polytetrafluoroethylene, polyvinyl, silicone resin, silicone, epoxy resin and transparent synthetic rubber. Silicates, water glass and quartz glass, for example, can be selected as glass.

According to at least one embodiment, the conversion element is designed as a potting element. For this purpose, the luminophore and possibly the base luminophore can be embedded in the matrix material. The potting element can, for example, be arranged in the recess of a housing and enclose the semiconductor chip. According to one embodiment, the potting element is a volume potting in which the luminophore and, if applicable, the base luminophore are evenly distributed in the matrix material. Alternatively, according to another embodiment, the luminophore and possibly the base luminophore are present in the potting element in sedimented form. A concentration gradient of the luminophore and, if applicable, the base luminophore in the matrix material is therefore present within the potting element, with the concentration of the luminophore and, if applicable, the base luminophore decreasing with increasing distance from the semiconductor chip.

According to at least one embodiment, the conversion element is designed as a conversion layer. The conversion layer can be applied in direct or indirect contact with the semiconductor chip. In the case of indirect contact, it can be applied to the semiconductor chip, in particular to its radiation exit surface, by means of an adhesive layer, for example, or there can be a potting between the semiconductor chip and the conversion element.

According to a further embodiment, the semiconductor chip, optional conversion element and possibly an adhesive layer can also all be surrounded by a potting. For example, the semiconductor chip, conversion element and optionally an adhesive layer are then arranged in the recess of a housing in which the potting is also arranged.

A potting can have a transmittance for primary radiation and/or secondary radiation of at least 85%, for example, 95%. Furthermore, a potting can be made of silicone or epoxy resin, for example.

According to at least one embodiment, two or more luminophores described herein with different compositions are present in the conversion element. In this case, the respective associated base luminophores may also be present in the conversion element.

Further advantageous embodiments and further embodiments of the luminophore, the component and the method result from the exemplary embodiments described below in conjunction with the figures.

### BRIEF DESCRIPTION OF THE DRAWINGS

FIG. 1 shows a schematic sectional view of a radiation-emitting component according to an exemplary embodiment.

FIGS. 2a and 2b show schematic sectional views of a radiation-emitting component according to exemplary embodiments.

FIG. 3 shows reflection spectra of luminophores according to exemplary embodiments.

FIG. 4 shows reflection spectra of luminophores according to exemplary embodiments.

Elements that are identical, similar or have the same effect are marked with the same reference symbols in the figures. The figures and the proportions of the elements shown in the figures are not to be regarded as true to scale. Rather, individual elements, in particular layer thicknesses, may be shown in exaggerated size for better visualization and/or understanding.

### DESCRIPTION

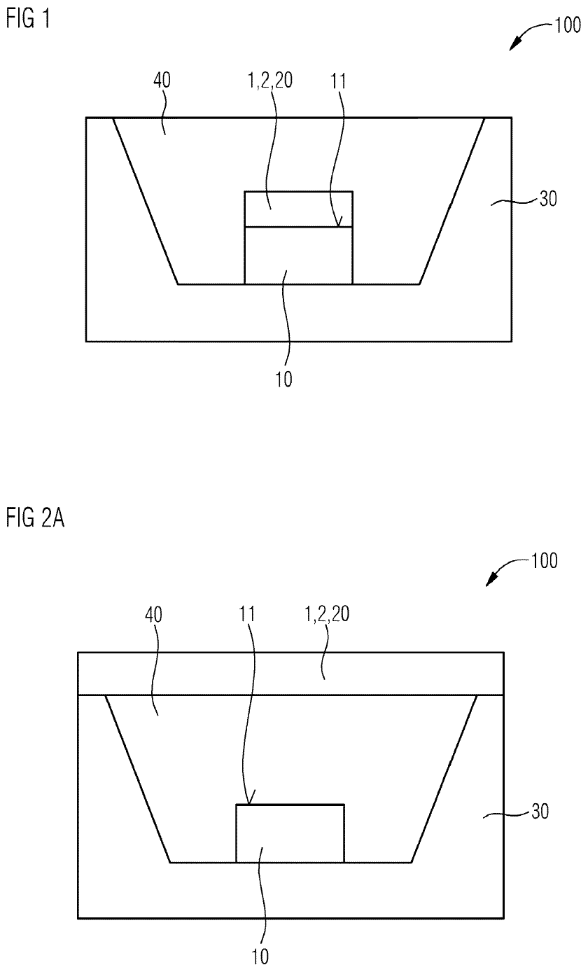

FIG. 1 shows a schematic sectional view of a radiation-emitting component according to an exemplary embodiment. The radiation-emitting component 100 has a semiconductor chip 10. During operation, the semiconductor chip 10 emits electromagnetic radiation of a first wavelength range (primary radiation) from a radiation exit surface 11. The semiconductor chip 10 has an epitaxially grown semiconductor layer sequence with an active zone that is suitable for generating electromagnetic radiation. The primary radiation has wavelengths in the blue and/or ultraviolet range, for example. In particular, the semiconductor chip 10 is an LED chip.

Furthermore, the component has a conversion element 20. The conversion element 20 either contains a matrix material in which the luminophore 1, in particular particles of the luminophore 1, is embedded, or the conversion element 20 has or consists of a ceramic formed from the luminophore 1. Alternatively, the conversion element 20 contains a matrix material in which the luminophore 1 and a base luminophore 2, in particular particles of the luminophore 1 and the base luminophore 2, are embedded, or the conversion element 20 has or consists of a ceramic formed from the luminophore 1 and the base luminophore 2.

The matrix material is selected from polymers such as polystyrene, polysiloxane, polysilazane, PMMA, polycarbonate, polyacrylate, polytetrafluoroethylene, polyvinyl, silicone resin, silicone, epoxy resin and transparent synthetic rubber, and glass such as silicates, water glass and quartz glass.

During operation, the luminophore 1 and, if applicable, the base luminophore 2 convert electromagnetic radiation of the first wavelength range into electromagnetic radiation of the second wavelength range (secondary radiation). If the primary radiation is not completely converted by the conversion element, the component thus emits mixed light composed of primary and secondary radiation.

The conversion element 20, which is designed here as a conversion layer, can either be applied directly to the semiconductor chip 10 or attached to it, for example by means of an adhesive layer (not explicitly shown here).

The semiconductor chip 10 with the conversion element 20 arranged thereon is arranged in the recess of a housing 30. The housing 30 has side surfaces that are beveled towards the semiconductor chip 10 and can be reflective. The semiconductor chip 10 and the conversion element 20 may be surrounded by a potting 40 in the housing 30, as shown here. However, the presence of a potting 40 is not absolutely necessary. The potting can be formed from a silicone or epoxy resin, for example, and has a transmittance for electromagnetic radiation of the active zone that is at least 85%, for example, 95%.

Alternatively, the housing 30 can also have no side walls and thus no recess and be designed as a carrier (not shown here).

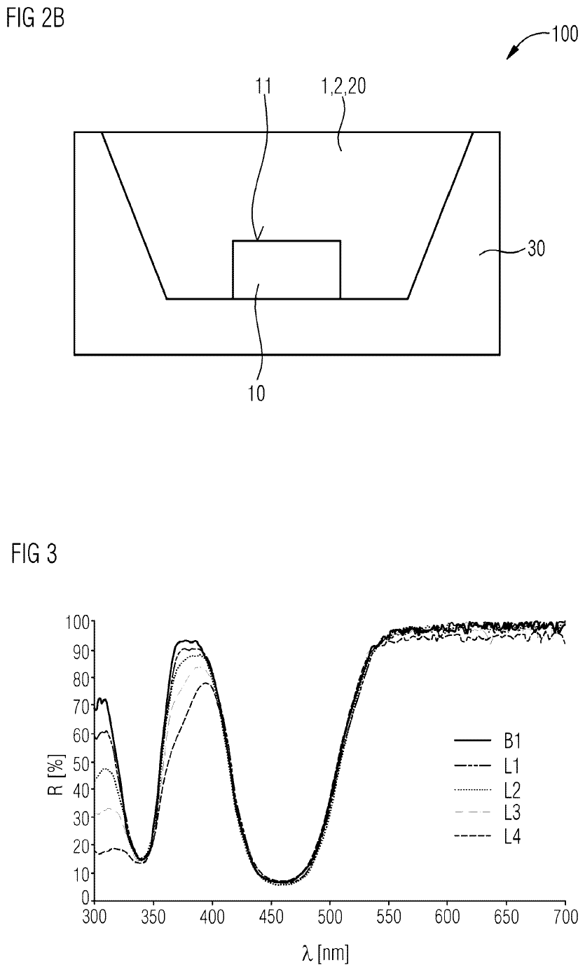

FIG. 2a shows another exemplary embodiment of a radiation-emitting component. The explanations made with reference to FIG. 1 apply to the elements with the same reference signs. In this embodiment example, the conversion element 20 is not arranged directly on the semiconductor chip 10, but spaced from it on the side of the potting 40 facing away from the semiconductor chip 10. Here too, the conversion element 20 is again formed as a conversion layer.

FIG. 2b shows another exemplary embodiment of a radiation-emitting component. The explanations given in relation to FIGS. 1 and 2a apply to the elements with the same reference signs. In this exemplary embodiment, the conversion element 20 is designed as a potting element and is arranged in the recess of the housing 30. Thereby it encloses the semiconductor chip 10. The potting element can either be designed as a volume potting element in which the luminophore 1 and optionally the base luminophore 2 are evenly distributed in the matrix material. Alternatively, the luminophore 1 and optionally the base luminophore 2 can be present in sedimented form. The concentration of the luminophore 1 and optionally the base luminophore 2 in the matrix material is then high close to the semiconductor chip 10 and decreases with increasing distance from the semiconductor chip 10.

The components shown in FIGS. 1 and 2 are LEDs, for example. For the sake of clarity, additional elements, such as electrical contacts, are not shown in FIGS. 1 and 2.

In the following, the luminophore 1 described here and the method for its production are explained with reference to exemplary embodiments.

The starting materials provided are the base luminophores according to the exemplary embodiments B1 (YAG:Ce³⁺ with a Ce³⁺ content of 2.0 mol %) and B2 (YAG:Ce³⁺ with a Ce³⁺ content of 2.8 mol %). These each contain the oxide Y₃Al₅O₁₂ as oxide or host material and the rare earth element Ce as activator element with the first valency 3+.

The base luminophores B1 and B2 are subjected to post-sintering. For this purpose, they are heated in air for three hours at different temperatures and thus oxidized to form the luminophore 1. Depending on the temperature applied, the luminophores according to the exemplary embodiments L1 to L4 result from the base luminophore B1 and the luminophores L5 and L6 from the base luminophore B2.

In the following Tables 1 and 2, the exemplary embodiments L1 to L6 are listed with their respective manufacturing temperatures T, the relative quantum efficiency QEᵣₑₗ compared to the respective base luminophore, the minimum remission R₄₅₀₋₄₇₀ at the wavelengths 450 nm to 470 nm, the relative brightness Hᵣₑₗ, as well as the half-width FWHM and the dominant wavelength λ_{dom} of the associated emission spectra.

TABLE 1

| | T | QEᵣₑₗ | R₄₅₀₋₄₇₀ | Hᵣₑₗ | FWHM | λ_{dom} |
|---|---|---|---|---|---|---|
| | [° C.] | [%] | [%] | [%] | [nm] | [nm] |
| B1 | | 100 | 6.2 | 93.8 | 113 | 571 |
| L1 | 750 | 97.7 | 5.9 | 92.0 | 113 | 571 |
| L2 | 850 | 90.3 | 6.7 | 84.2 | 112 | 571 |
| L3 | 950 | 82.6 | 6.8 | 77.0 | 111 | 571 |
| L4 | 1150 | 57.7 | 7.2 | 53.5 | 111 | 570 |

TABLE 2

| | T | QEᵣₑₗ | R₄₅₀₋₄₇₀ | Hᵣₑₗ | FWHM | λ_{dom} |
|---|---|---|---|---|---|---|
| | [° C.] | [%] | [%] | [%] | [nm] | [nm] |
| B2 | | 100 | 5.1 | 94.9 | 113 | 571 |
| L5 | 750 | 79.6 | 5.7 | 75.1 | 113 | 571 |
| L6 | 850 | 47.4 | 5.8 | 44.7 | 112 | 571 |

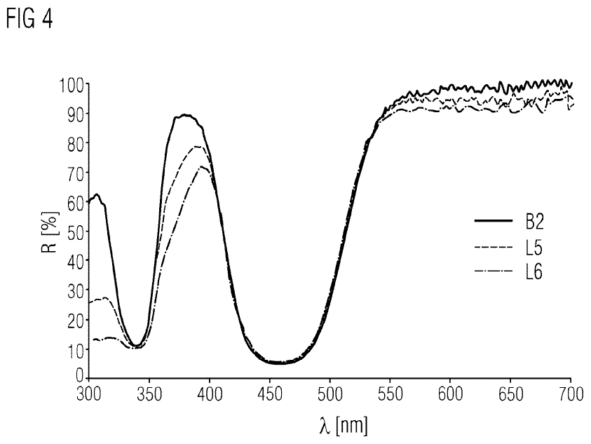

The corresponding reflection spectra are shown in FIGS. 3 and 4. FIG. 3 shows the reflectance spectra of the base luminophore B1 and the luminophores L1 to L4, FIG. 4 shows the reflectance spectra of the base luminophore B2 and the luminophores L5 and L6. In each case, the wavelength λ in nm is plotted against the reflectance R in %.

It is easy to observe that as the temperature increases during oxidation of the base luminophore, the relative quantum efficiency and thus the relative brightness of the luminophores decreases, which is due to the fact that the content of activator element Ce³⁺ decreases, which means that the content of Ce⁴⁺ in the respective luminophores increases.

At the same time, the absorption behavior of the base luminophore in the luminophores is retained, which can be seen in particular from the almost unchanged minimum remission R₄₅₀₋₄₇₀ at the wavelengths 450 nm and 470 nm. In the spectra in FIGS. 3 and 4, this can be seen from the complete overlap of the curves in the range between 450 nm and 470 nm.

Furthermore, the emission behavior of the resulting luminophores is also retained, as can be seen from the almost unchanged half-width of the emission spectra.

The substantially identical dominant wavelength Adom of the luminophores compared to the respective base luminophores shows that the base luminophores can be oxidized to the luminophores without a change in the color location of the emitted radiation.

The luminophores described here are therefore very well suited for use in components that are to be provided in various brightness levels.

The features and exemplary embodiments described in connection with the figures can be combined with one another according to further exemplary embodiments, even if not all combinations are explicitly described. Furthermore, the exemplary embodiments described in connection with the figures may alternatively or additionally have further features as described in the general part.

The present disclosure is not limited to the description based on the exemplary embodiments. Rather, the present disclosure includes any new feature as well as any combination of features, which includes in particular any combination of features in the patent claims, even if this feature or combination itself is not explicitly stated in the patent claims or embodiments.

### LIST OF REFERENCE SYMBOLS

1 Luminophore
2 Base luminophore
10 Semiconductor chip
11 Radiation exit surface
20 Conversion element
30 Housing
40 Potting
100 Radiation-emitting component
B1 Base luminophore according to an exemplary embodiment
B2 Base luminophore according to an exemplary embodiment
L1 Luminophore according to an exemplary embodiment
L2 Luminophore according to an exemplary embodiment
L3 Luminophore according to an exemplary embodiment
L4 Luminophore according to an exemplary embodiment
L5 Luminophore according to an exemplary embodiment
L6 Luminophore according to an exemplary embodiment

1-16. (canceled)

17. A radiation emitting component comprising:
a semiconductor chip that emits electromagnetic radiation of a first wavelength range during operation,
a conversion element comprising a luminophore, which converts electromagnetic radiation of the first wavelength range into electromagnetic radiation of a second wavelength range which is partially different from the first wavelength range,
wherein the luminophore comprises:
a host material containing an oxide,
an activator element comprising a rare earth element having a first valency, and
wherein the rare earth element has a second valency that is greater than the first valency, and
wherein the luminophore has the general formula
(Y, Lu, Gd, Tb)₃(Al₁₋ₓ,Gaₓ)₅O₁₂:Ce_{y}³⁺Ce_{1-y}⁴⁺
wherein 0≤x≤1 and 0<y<1

18. The radiation-emitting component according to claim 17, wherein the conversion element additionally comprises a base luminophore, wherein the base luminophore differs from the luminophore only in that it is free of the rare earth element having the second valency.

19. The radiation-emitting component according to claim 17,
wherein the radiation-emitting component is a light-emitting diode or a laser.

20. The radiation-emitting component according to claim 17,
wherein the conversion element comprises a mixture of the luminophore (Y, Lu, Gd, Tb)₃(Al₁₋ₓ,Gaₓ)₅O₁₂:Ce_{y}³⁺Ce_{1-y}⁴⁺ wherein 0≤x≤1 and 0<y<1 and the base luminophore (Y, Lu, Gd, Tb)₃(Al₁ₓ,Gaₓ)₅O₁₂:Ce³⁺ wherein 0≤x≤1.

21. The radiation-emitting component according to claim 18, wherein a ratio of luminophore to base luminophore in the conversion element is selected from 100:0, 80:20, and 60:40.

22. The radiation-emitting component according to claim 17,
wherein the luminophore is free of divalent co-dopands.

23. The radiation-emitting component according to claim 17,
wherein the luminophore has an absorption range with an absorption maximum,
wherein the absorption maximum has a position which is substantially identical to a position of an absorption maximum of a base luminophore, and
wherein the base luminophore differs from the luminophore only in that it is free of the rare earth element having the second valency.

24. The radiation-emitting component according to claim 23,
wherein the absorption range of the luminophore is at least in the UV to blue wavelength range of the electromagnetic spectrum.

25. The radiation-emitting component according to claim 17,
wherein the luminophore has a quantum efficiency that is reduced compared to a quantum efficiency of a base luminophore, and
wherein the base luminophore differs from the luminophore only in that it is free of the rare earth element having the second valency.

26. The radiation-emitting component according to claim 17,
wherein an electromagnetic radiation emitted from the luminophore has a dominant wavelength which is substantially identical to a dominant wavelength of a base luminophore, and
wherein the base luminophore differs from the luminophore only in that it is free of the rare earth element having the second valency.

27. The radiation-emitting component according to claim 17,
wherein an electromagnetic radiation emitted by the luminophore has a half-width which is substantially identical to a half-width of a base luminophore, and
wherein the base luminophore differs from the luminophore only in that it is free of the rare earth element having the second valency.

28. The radiation-emitting component according to claim 17,
wherein the luminophore has a brightness which decreases with increasing proportion of the rare earth element having the second valency in the luminophore.

29. A luminophore, comprising:
a host material containing an oxide,
an activator element comprising a rare earth element having a first valency, and
wherein the rare earth element has a second valency, the second valency being greater than the first valency, and
wherein the luminophore has the general formula (Y, Lu, Gd, Tb)₃(Al₁₋ₓ,Gaₓ)₅O₁₂:Ce_{y}³⁺Ce_{1-y}⁴⁺
wherein 0≤x≤1 and 0<y<1.

30. A method for producing a luminophore comprising:
providing a base luminophore comprising:
a host material containing an oxide, and
an activator element comprising a rare earth element with a first valency,
oxidizing of the base luminophore to a luminophore comprising
the host material containing an oxide,
the activator element comprising a rare earth element having a first valency, and
wherein the rare earth element has a second valency, the second valency being greater than the first valency,
wherein the luminophore has the general formula:
(Y, Lu, Gd, Tb)₃(Al₁₋ₓ,Gaₓ)₅O₁₂:Ce_{y}³⁺Ce_{1-y}⁴⁺
where 0≤x≤1 and 0<y<1.

31. The method according to claim 30,
wherein the oxidation is carried out at a temperature from the range including 350° C. to including 1400° C.

32. The method according to claim 30,
wherein the oxidation is carried out in air or oxygen, and/or wherein the oxidation is carried out for a period of from including one hour up to and including five hours.

33. The method according to claim 30,
wherein the base luminophore (Y, Lu, Gd, Tb)₃(Al₁₋ₓ,Gaₓ)₅O₁₂:Ce³⁺ wherein 0≤x≤1 is provided and is oxidized to the luminophore (Y, Lu, Gd, Tb):(Al₁₋ₓ,Gaₓ)₅O₁₂:Ce_{y}³⁺Ce_{1-y}⁴⁺ wherein 0≤x≤1 and 0<y<1.

34. The method according to claim 30,
wherein no divalent co-dopands are used.
